(19) United States
(12) Patent Application Publication
(10) Pub. No.: US 2012/0273035 A1
(43) Pub. Date: Nov. 1, 2012

(54) PHOTOVOLTAIC DEVICE WITH SURFACE PERTURBATIONS CONFIGURED FOR RESONANT AND DIFFUSIVE COUPLING

(76) Inventors: Karl William Koch, III, Elmira, NY (US); Daniel Aloysius Nolan, Corning, NY (US)

(21) Appl. No.: 13/445,250

(22) Filed: Apr. 12, 2012

Related U.S. Application Data
(60) Provisional application No. 61/480,808, filed on Apr. 29, 2011.

(51) Int. Cl. H01L 31/0232; H01L 31/0687; H01L 31/0236

(52) U.S. Cl. 136/255; 136/259

(57) ABSTRACT

Photovoltaic devices are contemplated where TCO layers of the device are provided with a distribution of resonant coupling periodicities Λ_{R} while the glass substrate of the device is provided with a distribution of diffusive coupling periodicities Λ_{D}. The respective surface textures defining these periods are superimposed at an interface with the photoelectric conversion layer and collectively define a frequency-dependent power spectral density inversion in the device. Additional embodiments are disclosed and contemplated.

### CROSS-REFERENCE TO RELATED APPLICATIONS

This application claims the benefit of priority under 35 U.S.C. §119 of U.S. Provisional Application Ser. No. 61/480,808 filed on Apr. 29, 2011 the content of which is relied upon and incorporated herein by reference in its entirety.

This application is related to copending U.S. patent application Ser. No. 12/263,583, filed Nov. 3, 2008, U.S. patent application Ser. No. 13/033175, filed Feb. 23, 2011 and U.S. application Ser. No. 13/033,075 filed Feb. 23, 2011, but does not claim priority thereto.

### BACKGROUND

The present disclosure relates to photovoltaic devices including, but not limited to, photodiodes, solar cells, photovoltaic modules, photovoltaic arrays, or any device comprising a layer or layers that are configured to convert light into electricity or otherwise exhibit a photovoltaic effect, i.e., the creation of a voltage or a corresponding electric current in a material upon exposure to light.

### BRIEF SUMMARY

According to the subject matter of the present disclosure, photovoltaic devices are contemplated where TCO layers of the device are provided with a distribution of resonant coupling periodicities Λ_{R} while the glass substrate of the device is provided with a distribution of diffusive coupling periodicities Λ_{D}. The respective surface textures defining these periods are superimposed at an interface with the photoelectric conversion layer and collectively define a frequency-dependent power spectral density inversion in the device.

Contemplated photovoltaic devices will typically comprise an incident-side glass substrate, a backside reflector, a plurality of transparent conductive oxide (TCO) layers, and a photoelectric conversion layer. The incident-side TCO layer of these devices comprises surface perturbations characterized by a distribution of resonant coupling periodicities Λ_{R}. Similarly, the incident-side glass substrate of these devices comprises surface perturbations characterized by a distribution of diffusive coupling periodicities Λ_{D}. In accordance with many embodiments of the present disclosure, the distribution of resonant coupling periodicities Λ_{R} and the distribution of diffusive coupling periodicities Λ_{D} are superimposed at an incident-side interface with the photoelectric conversion layer and collectively define a frequency-dependent power spectral density inversion. In accordance with other embodiments of the present disclosure, the power spectral density of the distribution of diffusive coupling periodicities Λ_{D} is more heavily weighted over relatively large coupling periods than the distribution of resonant coupling periodicities Λ_{R} while the power spectral density of the distribution of resonant coupling periodicities Λ_{R} is more heavily weighted over relatively small coupling periods than the distribution of diffusive coupling periodicities Λ_{R}.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 is a schematic illustration of a single cell photovoltaic device according to one embodiment of the present disclosure;

FIG. 2 is an image of a surface comprising surface perturbations characterized by a distribution of a plurality of coupling periodicities;

FIG. 3 is a graphical representation of diffusive and resonant coupling periodicity distributions according to one embodiment of the present disclosure;

FIG. 4 illustrates selected ranges of diffusive and resonant coupling periodicities superimposed on the graphical representation of FIG. 3; and

FIG. 5 is a schematic illustration of a tandem cell photovoltaic device according to one embodiment of the present disclosure.

### DETAILED DESCRIPTION

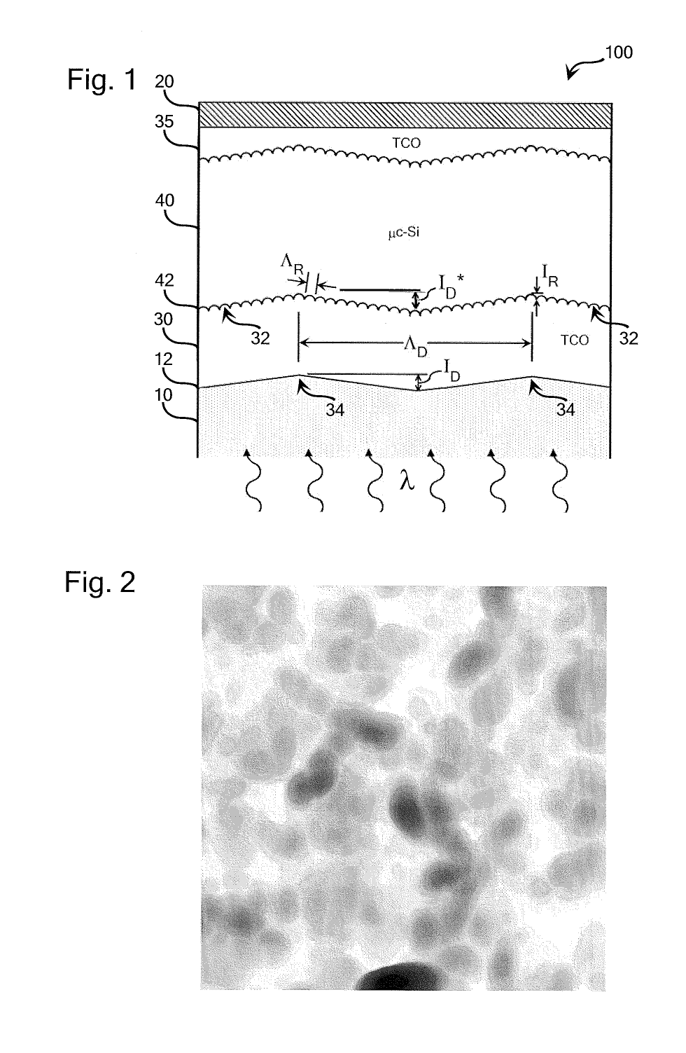

FIG. 1 is a schematic illustration of a photovoltaic device 100 comprising an incident-side glass substrate 10, a backside reflector 20, a plurality of transparent conductive oxide (TCO) layers 30, 35, and a photoelectric conversion layer 40. The photoelectric conversion layer 40 and the TCO layers 30, 35 are positioned between the incident-side glass substrate 10 and the backside reflector 20 and are arranged such that incident light λ propagating from the incident-side glass substrate 10 to the backside reflector 20 passes through the incident-side TCO layer 30 prior to passing through the photoelectric conversion layer 40 and the backside TCO layer 35.

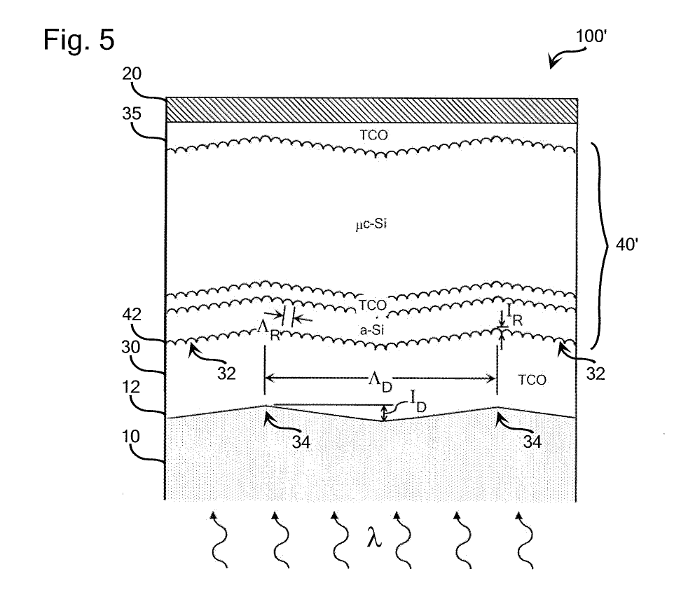

In operation, the incident light λ passes through the incident-side glass substrate 10 into the photoelectric conversion layer 40. The semiconductor material of the photoelectric conversion layer, which may be a single junction amorphous silicon conversion layer, as is illustrated schematically in FIG. 1, or a tandem conversion layer, as is illustrated schematically in FIG. 5, includes a p-n junction, which has the characteristic of creating unbound charges (electrons and holes) and generating a voltage across the TCO layers 30, 35 when light passes through the junction. As is illustrated in FIG. 5, a tandem conversion layer 40′ typically comprises one or more microcrystalline silicon, doped amorphous silicon, or amorphous germanium silicon layers in addition to an amorphous silicon layer and an intervening TCO layer. A typical tandem cell 100′ incorporates the aforementioned incident-side glass substrate 10, tandem conversion layer 40′, incident-side and backside TCO layers 30, 35 and backside reflector 20. In either case, it is also contemplated that the semiconductor material need not be silicon-based. Rather, it may be comprised of a variety of suitable photovoltaic semiconductor materials including, but not limited to, thin-film photovoltaic technologies based on CIGS and CdTe, both of which are well-documented in the state of the art.

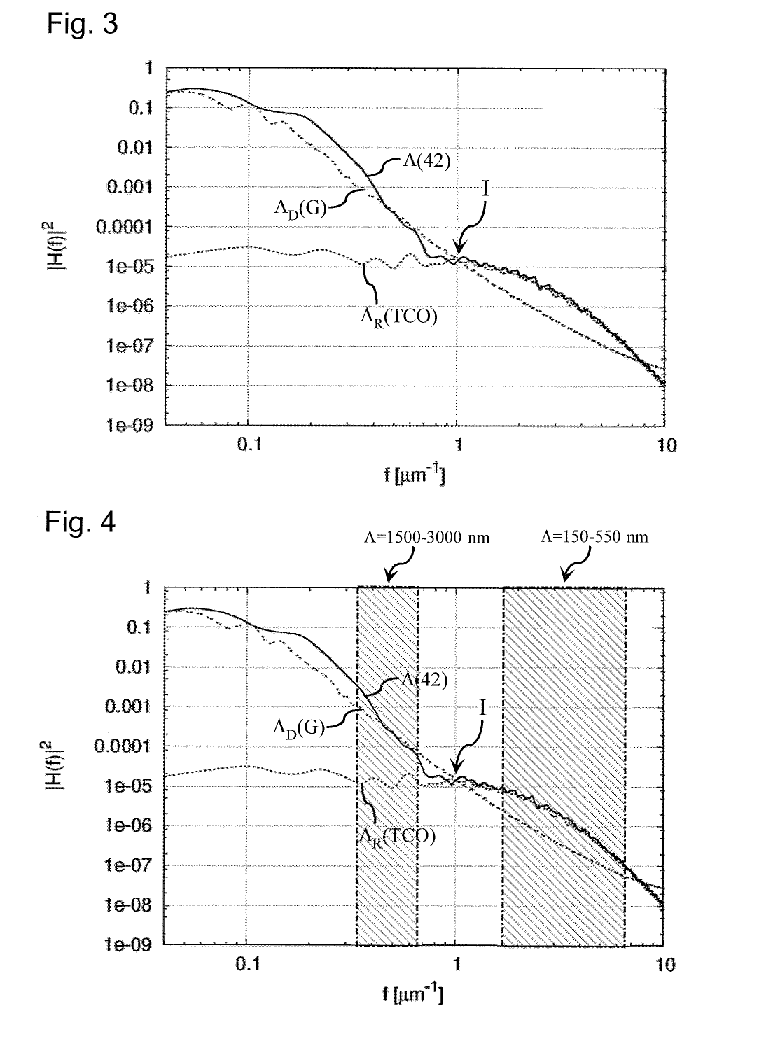

Referring additionally to the graphs of FIGS. 3 and 4, photovoltaic devices according to the present disclosure can be fabricated such that the incident-side TCO layer 30 comprises surface perturbations 32 that are characterized by a distribution of a plurality of resonant coupling periodicities Λ_{R}. Further, the incident-side glass substrate 10 comprises surface perturbations 34 that are characterized by a distribution of a plurality of diffusive coupling periodicities Λ_{D}. Although the various embodiments of the present disclosure are described primarily with reference to the perturbations 32 on the incident-side TCO layer 30 and the superposition of the diffusive and resonant coupling periodicities Λ_{D}, Λ_{R} at the interface 42 of the incident-side TCO layer 30 with the photoelectric conversion layer 40, it is noted that the resulting texture will also typically be present at the interface of the backside TCO layer 35 with the photoelectric conversion layer 40.

In FIG. 1, the surface perturbations 32, 34 are spaced uniformly at two distinct coupling periodicities Λ_{D}, Λ_{R}. In practice, the surface perturbations 32 are somewhat irregular and the incident-side glass substrate 10 and TCO layer 30 are more accurately described as semi-smooth or textured surfaces comprising respective distributions of resonant coupling periodicities Λ_{R} and diffusive coupling periodicities Λ_{D}. The respective periodicities Λ_{R}, Λ_{D} are superimposed at the incident-side interface 42 with the photoelectric conversion layer 40. For example, FIG. 2 is an image of a surface comprising surface perturbations of the nature contemplated in the present disclosure.

The present inventors have recognized that this superposition of the periodicities Λ_{D}, Λ_{R} at the incident-side interface 42 cooperates with the backside reflector 20 to cause a significant portion of the incident light λ to become trapped within the photoelectric conversion layer 40. More specifically, the resonant coupling periodicities Λ_{R} act to couple incident light into selected waveguide modes of the TCO/silicon/TCO structure of the photovoltaic device 100, while the diffusive coupling periodicities Λ_{D} couple light from the selected waveguide modes to other guided modes of the structure. The diffusive process enables light to linger in the absorbing core of the waveguide for a longer time than would be possible without these perturbations. This lingering enables increased absorption of the light and thus increased conversion efficiency. According to one embodiment of the present disclosure, the diffusive coupling periodicities Λ_{D} of the incident-side glass substrate 10 are configured for diffusive coupling to waveguide modes corresponding to an effective refractive index that is approximately half way between the index of the photoelectric conversion layer 40 and the index of the incident-side TCO layer 30.

FIG. 3 represents graphically the resonant and diffusive coupling periodicity distributions as a plot of power spectral density |H(f)²| as a function of perturbation spatial frequency f. The power spectral density |H(f)²| can be calculated by generating a Fourier series representation of the surface and using the representation to show the amplitude of each spatial frequency component, i.e., how much of each spatial frequency component is represented on the surface at hand. For example, in FIG. 3, the distribution Λ_{D}(G) representing the diffusive coupling periodicities Λ_{D} of the incident-side glass substrate 10 is more heavily weighted over lower frequencies (larger coupling periods) than the distribution Λ_{R}(TCO) representing the resonant coupling periodicities Λ_{R} of the incident-side TCO layer 30. FIG. 3 also shows a distribution Λ(42) representing periodicities Λ_{R}, Λ_{D} superimposed at the incident-side interface 42.

Collectively, as is illustrated in FIG. 3, the superimposed distributions Λ_{D}(G), Λ_{R}(TCO) define a frequency-dependent power spectral density inversion I. The power spectral density inversion I is formed because the distribution Λ_{D}(G) has a relatively high amplitude at relatively low frequencies, while the distribution Λ_{R}(TCO) has a relatively high amplitude at relatively high frequencies. Stated differently, the superimposed distribution is dominated in the frequency domain above I by perturbations of the incident side TCO layer 30 and below I by perturbations of the incident-side glass substrate 10. More specifically, the power spectral density inversion I is formed by (i) diffusive coupling periodicities Λ_{D} at higher power spectral densities than corresponding resonant coupling periodicities Λ_{R} over a range of relatively low spatial frequencies and (ii) resonant coupling periodicities Λ_{R} at higher power spectral densities than corresponding diffusive coupling periodicities Λ_{D} over a range of relatively high spatial frequencies.

Suitable ranges for the respective low and high spatial frequencies can vary widely according to the concepts of the present disclosure and will be at least partially dependent upon the thickness of the incident-side TCO layer 30. It is contemplated that the power spectral density inversion I can, in many cases, be established at a frequency of between approximately 0.5 μm⁻¹ (Λ≈2000 nm) and approximately 2.0 μm⁻¹ (Λ≈500 nm). As is the case for the inversion I illustrated in FIG. 3, it is also contemplated that the range of relatively low spatial frequencies forming the frequency-dependent power spectral density inversion I should, in many cases, extend for at least approximately 0.5 μm⁻¹. Similarly, the range of relatively high spatial frequencies forming the frequency-dependent power spectral density inversion I should, in many cases, extend for at least approximately 1.0 μm⁻¹.

FIG. 4 illustrates one example of suitable ranges for the respective low and high spatial frequencies superimposed over the distributions of FIG. 3 for clarity. In FIG. 4, the diffusive coupling periodicities Λ_{D} of the incident-side glass substrate are at higher power spectral densities than corresponding resonant coupling periodicities Λ_{R} of the incident-side TCO layer between approximately 1500 nm and approximately 3000 nm to enhance diffusive coupling among waveguide modes of the photoelectric conversion layer. Similarly, the resonant coupling periodicities Λ_{R} of the incident-side TCO layer are at higher power spectral densities than corresponding diffusive coupling periodicities Λ_{D} of the incident-side glass substrate between approximately 150 nm and approximately 550 nm to optimize trapping of wavelengths greater than 550 nm in selected waveguide modes of the photoelectric conversion layer and to limit trapping to wavelengths within the absorption edge of the photoelectric conversion layer.

Potentially optimum periods for the resonant coupling periodicities Λ_{R} are between approximately 75 nm and approximately 550 nm. However, for wavelengths from 350 nm to 575 nm, 250 nm amorphous silicon layers typically absorb nearly all of the light transmitted into the a-Si layer. Accordingly, in particular implementations of the concepts of the present disclosure, light trapping processes are not as important, relatively speaking, for wavelengths from 350 nm to 575 nm. To optimize trapping of wavelengths greater than 550 nm in selected waveguide modes of the photoelectric conversion layer 40, the resonant coupling periodicities Λ_{R} of the incident-side TCO layer 30 should be greater than or equal to approximately 150 nm. In addition, it is contemplated that the resonant coupling periodicities Λ_{R} of the incident-side TCO layer should be less than or equal to approximately 550 nm to limit trapping to wavelengths within the absorption edge of the photoelectric conversion layer 40.

It is contemplated that the optimum periods for the diffusive coupling among the waveguide modes of the system can be determined by referring to the effective index difference between the modes, which varies as a function of the wavelength and the order of the mode. Higher-order modes close to the fundamental mode have a smaller difference in effective index with those modes adjacent to them, while higher order modes closer to cutoff (smaller effective index) have a larger difference in effective index with the modes adjacent to them. The present inventors have recognized that the optimal diffusive grating coupling period is related to the wavelength of the light divided by the effective index difference of the resonantly coupled modes. This optimal period varies from 280 nm to greater than 200 gm. However, it is contemplated that optimal diffusive coupling periodicities Λ_{D} are likely to fall between 550 nm and 3 μm, if the intent is to couple to modes near the middle of the available effective index range (e.g., n_{eff}=3.0).

More generally, surface textures with Fourier components corresponding to diffusive coupling periodicities Λ_{D} between 150 nm and 3 μm represent surfaces with desirable light trapping capabilities. In many cases, a full spectrum of diffusive coupling periodicities Λ_{D} should be used to couple the guided modes of the structure amongst themselves. It is contemplated that the spectrum can vary from approximately 280 nm to approximately 20 μm, with a preferable range being between approximately 500 nm and approximately 5 μm. It is also contemplated that the diffusive coupling periodicities Λ_{D} of the incident-side glass substrate 10 can be contained between approximately 1500 nm and approximately 3000 nm to enhance diffusive coupling among waveguide modes of the photoelectric conversion layer and inhibit coupling to untrapped or radiative modes of the photoelectric conversion layer.

Generally, as is illustrated in FIGS. 1 and 5, the surface perturbations of the incident-side glass substrate 10 are presented independently of, and do not contribute substantially to, the perturbations and resonant coupling periodicities Λ_{R} of the incident-side TCO layer 30. In this manner, care can be taken to preserve the integrity of the interface 12 where the incident-side glass substrate 10 meets the incident-side TCO layer 30 because it is not necessary to incorporate the resonant coupling periodicities Λ_{R} of the incident-side TCO layer 30 in the surface of the incident-side glass substrate 10. For example, to inhibit void formation at this interface 12, the distribution that represents the diffusive coupling periodicities Λ_{D}, or at least a substantial entirety thereof, can be controlled independently to generally cover coupling periods greater than approximately 280 nm because periods less than 280 nm are not likely to be useful and can lead to optical backscattering or other deleterious optical or electrical effects in devices of the present disclosure.

In practicing embodiments of the of the present disclosure requiring superposition of the periodicities Λ_{D}, Λ_{R} at the incident-side interface 42 with the photoelectric conversion layer 40, it will be necessary to preserve the relatively long period texture of the incident-side glass substrate 10 so that it presents itself at the incident-side interface 42. To do so, care should be taken to ensure that the thickness of the incident-side TCO layer 30 is not excessive. As a general rule, it is contemplated that this thickness limitation will not be difficult to overcome with available TCO materials and fabrication technology because the diffusive coupling periodicities Λ_{D} of the incident-side glass substrate 10 are relatively large, e.g., greater than approximately 1000 nm (f=1 μm⁻¹) in the example illustrated in FIGS. 3 and 4, and will be readily preserved across a TCO layer thickness of approximately 100 nm to approximately 1000 nm.

Referring to FIGS. 1 and 5, the respective amplitudes of the surface perturbations I_{R}, I_{D} will also be a significant factor in attempting to maximize trapping in the waveguide structure of the photoelectric conversion layer 40 and will vary depending upon the desired periodicity of the surface perturbations and the thickness and properties of the incident-side TCO layer 30. For example, it is contemplated that care should be taken to monitor the characteristics of the incident-side TCO layer 30 as respective amplitudes of the surface perturbations I_{R}, I_{D} are selected because excessively large amplitudes can degrade the optical and electrical characteristics of the incident-side TCO layer 30. In many cases, larger amplitudes reduce the amount of energy coupled into selected waveguide modes of the waveguide structure of the photovoltaic device 100. It is contemplated that a suitable perturbation amplitude I_{R} for resonant coupling in a 2 μm thick photovoltaic device will be between approximately 100 nm and approximately 150 nm. More generally, it is contemplated that resonant coupling amplitudes I_{R} between approximately 100 nm and approximately 200 nm will be suitable for photoelectric conversion layer thicknesses between approximately 2 μm and approximately 5 μm. Similarly, to help optimize diffusive coupling among waveguide modes of the photoelectric conversion layer 40 and to further inhibit void formation at an interface of the incident-side glass substrate 10 and the incident-side TCO layer 30, it is contemplated that suitable surface perturbations of the incident-side glass substrate will be characterized by a diffusive coupling amplitude I_{D} manifesting itself as an effective diffusive coupling amplitude I_{D}* at the interface 42 of the incident-side TCO layer 30 and the photoelectric conversion layer 40. Typically, the thickness of the incident-side TCO layer 30 will lead to some degree of variation between the diffusive coupling amplitude I_{D} and the effective diffusive coupling amplitude I_{D}*. For example, and not by way of limitation, suitable effective diffusive coupling amplitudes I_{D}* will typically fall between approximately 100 nm and approximately 200 nm, for photoelectric conversion layer thicknesses between approximately 2 μm and approximately 5 μm.

The incident-side and backside TCO layers 30, 35 are transparent electrodes, typically presented as a film of fluorine doped-SnO₂, or boron or aluminum doped-ZnO, or cadmium stannate (Cd₂SnO₄), with a thickness on the order of approximately 1 μm. The TCO layers 30, 35 can be textured by various techniques. For example, in the case of SnO₂ or ZnO films deposited by chemical vapor deposition (CVD), the texture can be controlled by controlling deposition conditions and film thickness. For sputtered films, the texture can be modified by etching such as wet etching or plasma etching. Plasma etching has also been used with CVD ZnO to control texture.

The incident-side glass substrate 10 of the photovoltaic device 100 can also be textured in a variety of ways. For example, and not by way of limitation, texturing in some conventional thin film silicon devices is accomplished by incorporating SiO₂ particles in a binder and depositing the matrix on the substrate. This type of texturing is typically done using a sol-gel type process where spherical particles are suspended in liquid and the substrate is drawn through the liquid, and subsequently sintered. The spherical particles are held in place by the sintered gel. Many additional methods have been explored for creating a textured surface prior to TCO deposition. These methods include sandblasting, polystyrene microsphere deposition and etching, and chemical etching.

According to one contemplated process, an inorganic transparent substrate is provided and an adhesive is applied to the surface of the substrate. Particles are applied to the adhesive to form a coated substrate, and the coated substrate is heated to form a light scattering inorganic substrate. In another contemplated process, a monolayer of inorganic particles is formed on the surface of the transparent substrate and the coated substrate is heated above its softening point to form the light scattering surface. The inorganic particles can be pressed into the surface.

For the purposes of describing and defining the present invention, it is noted that reference herein to a variable being a “function” of a parameter or another variable is not intended to denote that the variable is exclusively a function of the listed parameter or variable. Rather, reference herein to a variable that is a “function” of a listed parameter is intended to be open ended such that the variable may be a function of a single parameter or a plurality of parameters. It is also noted that recitations herein of “at least one” component, element, etc., should not be used to create an inference that the alternative use of the articles “a” or “an” should be limited to a single component, element, etc.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the terms “substantially” and “approximately” are utilized herein to represent the inherent degree of uncertainty that may be attributed to any quantitative comparison, value, measurement, or other representation. The terms “substantially” and “approximately” are also utilized herein to represent the degree by which a quantitative representation may vary from a stated reference without resulting in a change in the basic function of the subject matter at issue.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Rather, the claims appended hereto should be taken as the sole representation of the breadth of the present disclosure and the corresponding scope of the various inventions described herein. Further, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

1. A photovoltaic device comprising an incident-side glass substrate, a backside reflector, a plurality of transparent conductive oxide (TCO) layers, and a photoelectric conversion layer, wherein:
the photoelectric conversion layer and the plurality of TCO layers are positioned between the incident-side glass substrate and the backside reflector and are arranged such that incident light propagating from the incident-side glass substrate to the backside reflector passes through an incident-side TCO layer prior to passing through the photoelectric conversion layer and a backside TCO layer;
the incident-side TCO layer comprises surface perturbations characterized by a distribution of resonant coupling periodicities Λ_{R};
the incident-side glass substrate comprises surface perturbations characterized by a distribution of diffusive coupling periodicities Λ_{D}; and
the distribution of resonant coupling periodicities Λ_{R} and the distribution of diffusive coupling periodicities Λ_{D} are superimposed at an incident-side interface with the photoelectric conversion layer and collectively define a frequency-dependent power spectral density inversion formed by (i) diffusive coupling periodicities Λ_{D} at higher power spectral densities than corresponding resonant coupling periodicities Λ_{R} over a range of relatively low spatial frequencies and (ii) resonant coupling periodicities Λ_{R} at higher power spectral densities than corresponding diffusive coupling periodicities Λ_{D} over a range of relatively high spatial frequencies.

2. The photovoltaic device as claimed in claim 1 wherein the power spectral density inversion is at a frequency of between approximately 0.5 μm⁻¹ (Λ≈2000 nm) and approximately 2.0 μm⁻¹ (Λ≈500 nm).

3. The photovoltaic device as claimed in claim 1 wherein:
the range of relatively low spatial frequencies of the frequency-dependent power spectral density inversion is at least approximately 0.5 μm⁻¹; and
the range of relatively high spatial frequencies of the frequency-dependent power spectral density inversion is at least approximately 1.0 μm⁻¹.

4. The photovoltaic device as claimed in claim 1 wherein:
the diffusive coupling periodicities Λ_{D} of the incident-side glass substrate are at higher power spectral densities than corresponding resonant coupling periodicities Λ_{R} of the incident-side TCO layer between approximately 1500 nm and approximately 3000 nm to enhance diffusive coupling among waveguide modes of the photoelectric conversion layer.

5. The photovoltaic device as claimed in claim 4 wherein the diffusive coupling periodicities Λ_{D} of the incident-side glass substrate are configured for diffusive coupling to waveguide modes corresponding to an effective refractive index that is approximately half way between the index of the photoelectric conversion layer and the index of the incident-side TCO layer.

6. The photovoltaic device as claimed in claim 1 wherein the resonant coupling periodicities Λ_{R} of the incident-side TCO layer are at higher power spectral densities than corresponding diffusive coupling periodicities Λ_{D} of the incident-side glass substrate between approximately 150 nm and approximately 550 nm to optimize trapping of wavelengths greater than 550 nm in selected waveguide modes of the photoelectric conversion layer and to limit trapping to wavelengths within the absorption edge of the photoelectric conversion layer.

7. A photovoltaic device as claimed in claim 1 wherein:
the diffusive coupling periodicities Λ_{D} of the incident-side glass substrate are at higher power spectral densities than corresponding resonant coupling periodicities Λ_{R} of the incident-side TCO layer between approximately 1500 nm and approximately 3000 nm to enhance diffusive coupling among waveguide modes of the photoelectric conversion layer and inhibit mode coupling to untrapped or radiative modes of the photoelectric conversion layer; and
the resonant coupling periodicities Λ_{R} of the incident-side TCO layer are at higher power spectral densities than corresponding diffusive coupling periodicities Λ_{D} of the incident-side glass substrate between approximately 150 nm and approximately 550 nm to optimize trapping of wavelengths greater than 550 nm in selected waveguide modes of the photoelectric conversion layer and to limit trapping to wavelengths within the absorption edge of the photoelectric conversion layer.

8. The photovoltaic device as claimed in claim 1 wherein the power spectral density inversion is at a periodicity greater than approximately 280 nm.

9. The photovoltaic device as claimed in claim 1 wherein the surface perturbations of the incident-side glass substrate are presented independently of the perturbations of the incident-side TCO layer.

10. The photovoltaic device as claimed in claim 1 wherein the surface perturbations of the incident-side glass substrate do not contribute substantially to the resonant coupling periodicities Λ_{R} of the incident-side TCO layer.

11. The photovoltaic device as claimed in claim 1 wherein substantially all of the surface perturbations of the incident-side glass substrate are characterized by an effective diffusive coupling amplitude I_{D}* between approximately 100 nm and approximately 200 nm to optimize diffusive coupling among waveguide modes of the photoelectric conversion layer.

12. The photovoltaic device as claimed in claim 11 wherein the effective diffusive coupling amplitude I_{D}* is between approximately 100 nm and approximately 200 nm and the photoelectric conversion layer thickness is between approximately 2 μm and approximately 5 μm.

13. The photovoltaic device as claimed in claim 1 wherein substantially all of the surface perturbations of the incident-side glass substrate are characterized by an effective diffusive coupling amplitude I_{D}* less than approximately 200 nm.

14. The photovoltaic device as claimed in claim 1 wherein substantially all of the surface perturbations of the incident-side TCO layer are characterized by a resonant coupling amplitude I_{R} that is between approximately 100 nm and approximately 150 nm to optimize light trapping in selected waveguide modes of the photoelectric conversion layer.

15. The photovoltaic device as claimed in claim 14 wherein the photoelectric conversion layer thickness is between approximately 2 μm and approximately 5 μm.

16. The photovoltaic device as claimed in claim 1 wherein the photoelectric conversion layer comprises a single junction amorphous silicon conversion layer or a tandem conversion layer comprising one or more microcrystalline silicon, doped amorphous silicon, or amorphous germanium silicon layers in addition to an amorphous silicon layer.

17. A photovoltaic device comprising an incident-side glass substrate, a backside reflector, a plurality of transparent conductive oxide (TCO) layers, and a photoelectric conversion layer, wherein:
the photoelectric conversion layer and the plurality of TCO layers are positioned between the incident-side glass substrate and the backside reflector and are arranged such that incident light propagating from the incident-side glass substrate to the backside reflector passes through an incident-side TCO layer prior to passing through the photoelectric conversion layer and a backside TCO layer;
the incident-side TCO layer comprises surface perturbations characterized by a distribution of resonant coupling periodicities Λ_{R};
the incident-side glass substrate comprises surface perturbations characterized by a distribution of diffusive coupling periodicities Λ_{D};
the distribution of resonant coupling periodicities Λ_{R} and the distribution of diffusive coupling periodicities Λ_{D} are superimposed at an incident-side interface with the photoelectric conversion layer;
the power spectral density of the distribution of diffusive coupling periodicities Λ_{D} is more heavily weighted over relatively large coupling periods than the distribution of resonant coupling periodicities Λ_{R} while the power spectral density of the distribution of resonant coupling periodicities Λ_{R} is more heavily weighted over relatively small coupling periods than the distribution of diffusive coupling periodicities Λ_{R}.

18. The photovoltaic device as claimed in claim 17 wherein:
the relatively large coupling periods occupy at least a portion of a range extending between approximately 1500 nm and approximately 3000 nm;
the power spectral density of the distribution of diffusive coupling periodicities Λ_{D} is at least one order of magnitude larger than the power spectral density of the distribution of resonant coupling periodicities Λ_{R} over the occupied portion of the range extending between approximately 1500 nm and approximately 3000 nm; and
the relatively small coupling periods occupy at least a portion of a range extending between approximately 150 nm and approximately 550 nm.

19. The photovoltaic device as claimed in claim 18 wherein the power spectral density of the distribution of resonant coupling periodicities Λ_{R} is at least one order of magnitude larger than the power spectral density of the distribution of diffusive coupling periodicities Λ_{D} over the occupied portion of the range extending between approximately 150 nm and approximately 550 nm.
